(19) United States
(12) Patent Application Publication
(10) Pub. No.: US 2025/0201726 A1
(43) Pub. Date: Jun. 19, 2025

(54) PACKAGE STRUCTURE AND MANUFACTURING METHOD THEREOF

(71) Applicant: Taiwan Semiconductor Manufacturing Company, Ltd., Hsinchu (TW)

(72) Inventor: Kuen-Shian Chen, New Taipei City (TW)

(73) Assignee: Taiwan Semiconductor Manufacturing Company, Ltd., Hsinchu (TW)

(21) Appl. No.: 18/403,616

(22) Filed: Jan. 3, 2024

Related U.S. Application Data
(60) Provisional application No. 63/609,350, filed on Dec. 13, 2023.

(51) Int. Cl. H01L 23/552; H01L 23/00; H01L 23/498; H01L 25/065

(52) U.S. Cl. CPC H01L 23/552; H01L 23/49816; H01L 23/49822; H01L 24/08; H01L 24/16; H01L 25/0652; H01L 2224/08146; H01L 2224/08155; H01L 2224/16146; H01L 2224/16157; H01L 2924/1421; H01L 2924/15311; H01L 2924/182

(57) ABSTRACT

A package structure includes a device structure and a wafer structure. The wafer structure is bonded to the device structure. The device structure includes a device die, a first redistribution layer, first hybrid bonds, and first shield portions. The first redistribution layer is disposed on the device die. The first hybrid bonds are electrically connected to the first redistribution layer. The first shield portions peripherally cover the first hybrid bonds for electromagnetic interference (EMI) shielding. The wafer structure includes a wafer substrate, a second redistribution layer, second hybrid bonds, and second shield portions. The second redistribution is disposed on the wafer substrate. The second hybrid bonds are respectively connected to the first hybrid bonds and the second redistribution layer. The second shield portions are connected to the first shield portions and the second redistribution layer. The second shield portions peripherally cover the second hybrid bonds for EMI shielding.

### CROSS-REFERENCE TO RELATED APPLICATION

This application claims the priority benefit of U.S. provisional application Ser. No. 63/609,350, filed on Dec. 13, 2023. The entirety of the above-mentioned patent application is hereby incorporated by reference herein and made a part of this specification.

### BACKGROUND

As the technology of semiconductor packages is advanced, the process speed of the package is enhanced, and the size of the package is further downsized. However, some issues or problems might be correspondingly raised due to the above advancements, such as high-intensity electromagnetic emission at high frequencies or short wavelengths.

In some semiconductor packages, the electromagnetic emission may be radiated from a semiconductor element that is adjacent to another semiconductor element and the connection therebetween. As an adjacent element located in the semiconductor package has a high intensity of electromagnetic emission, the electromagnetic emission the adjacent elements may adversely affects the operation of the other elements in the packages, particularly, in a high-density package, which may accommodate multiple elements in a rather small package dimension. Accordingly, the electromagnetic interference between semiconductor elements might become more severe in the high-density package, such as in a three-dimensional integrated circuit (3DIC) package.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic cross-sectional view of a package structure according to some exemplary embodiments of the disclosure.

FIG. 2A and FIG. 2C are schematic top views of hybrid bonds and shielding portions of the package structure according to some exemplary embodiments of the disclosure.

FIG. 2B is a schematic cross-sectional view of hybrid bonds and shielding portions of the package structure according to some exemplary embodiments of the disclosure.

FIG. 3 to FIG. 11 are schematic cross-sectional views of various stages in a manufacturing method of a package structure according to some exemplary embodiments of the disclosure.

FIG. 12 is a schematic cross-sectional view of a package structure according to another exemplary embodiment of the disclosure.

### DETAILED DESCRIPTION

The following disclosure provides many different embodiments, or examples, for implementing different features of the provided subject matter. Specific examples of components, values, operations, materials, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, terms, such as “first,” “second,” “third,” “fourth,” and the like, may be used herein for ease of description to describe similar or different element(s) or feature(s) as illustrated in the figures, and may be used interchangeably depending on the order of the presence or the contexts of the description.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

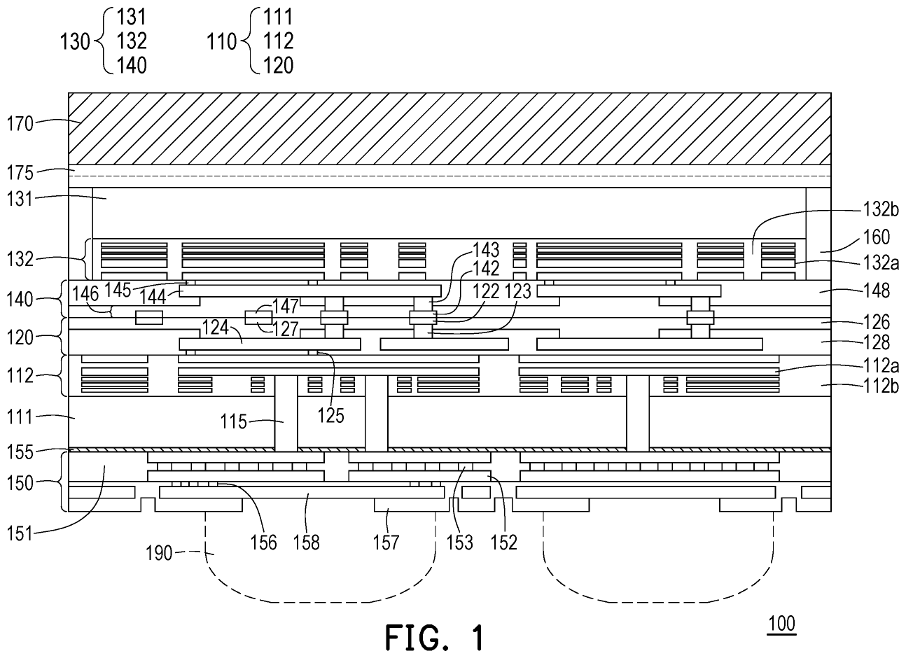

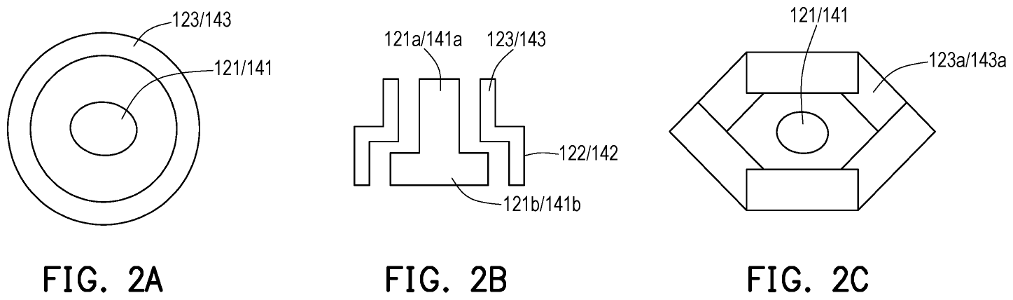

FIG. 1 is a schematic cross-sectional view of a package structure 100 according to some exemplary embodiments of the disclosure. FIG. 2A and FIG. 2C are schematic top views of hybrid bonds 121, 141 and shielding portions 122, 123, 142, 143 of the package structure 100 according to some exemplary embodiments of the disclosure. FIG. 2C is schematic cross-sectional view of hybrid bonds 121, 141 and shielding portions 122, 123, 142, 143 of the package structure 100 according to some exemplary embodiments of the disclosure. Referring to FIG. 1, FIG. 2A, and FIG. 2C, in the present embodiment, the package structure 100 may include a device structure 130 and a wafer structure 110 bonded to the device structure 130. In some embodiments, the device structure 130 may include a device die 131, a redistribution layer 132, and an interconnect structure 140 that includes hybrid bonds 141 and shielding portions 142, 143. As shown in FIG. 1, the redistribution layer 132 may be disposed on the device die 131 with electrical interconnection therebetween.

In the present embodiment, referring to FIG. 2A and FIG. 2B, the hybrid bonds 121, 141 are active hybrid bonds. The hybrid bonds 141 may be electrically connected to the redistribution layer 132. In the present embodiment, as shown in FIG. 2A and FIG. 2B, the shielding portions 142, 143 may peripherally surround and cover the hybrid bonds 141 for shielding the hybrid bonds 141 from electromagnetic interference (EMI) generated from, for example, electric potential different between the adjacent elements disposed in the package structure 100. In the present embodiment, the interconnect structure 140 may further include conductive layers 144 and the conductive vias 145 together connected to the hybrid bonds 141 and the shielding portions 142, 143. In the present embodiment, the shielding portions 142, 143 may be electrically connected to the redistribution layer 132 through the conductive layers 144 and the conductive vias 145 of the interconnect structure 140. In the present embodiment, the shielding portions 142, 143 may be electrically grounded to the device die 131 through electrical interconnection of the redistribution layer 132 for EMI shielding of the hybrid bonds 141. As shown in FIG. 1, in some embodiments, the redistribution layer 132 may include multiple conductive layers 132a embedded in a dielectric layer 132b for electrical connection between the interconnect structure 140 and the device die 131.

In some embodiments, the device die 131 described herein may be referred to as a chip or an integrated circuit (IC). In some embodiments, the device die 131 may include at least one wireless and radio frequency (RF) chip. In some embodiments, the device dic 131 may further include additional chip(s) of the same type or different types. For example, in an alternative embodiment, more than one device die 131 are provided, and the device dies 131, except for including at least one wireless and RF chip, may include the same or different types of chips selected from digital chips, analog chips or mixed signal chips, application-specific integrated circuit (“ASIC”) chips, sensor chips, memory chips, logic chips or voltage regulator chips. In an alternative embodiment, the device die 131 may be referred to as a chip or an IC of combination-type, and the device die 131 may be a WiFi chip simultaneously including both of a RF chip and a digital chip. The disclosure is not limited thereto.

In some embodiments, as shown in FIG. 1, the device die 131 and the redistribution layer 132 may be peripherally encapsulated by the encapsulation layer 160. In some other embodiments, the device die 131 may be further attached to a support silicon substrate 170 through an adhesive layer 175 for providing support to the device die 131 throughout the manufacturing process of the package 100.

Referring to FIG. 1 and FIG. 2A to FIG. 2C, in some embodiments, the hybrid bonds 141 may respectively include bump pads 141b and bonding vias 141a connected to the bonding pads 141b. In some embodiments, each of the shielding portions 142, 143 may respectively include a pad shielding portion 142 and a via shielding portion 143 connected to each other. Referring to FIG. 2B, each of the pad shielding portions 142 may peripherally surround and cover one of the bump pads 141b, and each of the via shielding portions 143 may peripherally surround and cover one of the bonding vias 141a. In the present disclosure, the shielding portions 142, 143 may conformally accommodate the bump pads 141b and the bonding vias 141a therewithin for EMI shielding of the hybrid bonds 141.

Referring to FIG. 2A and FIG. 2B, in some embodiments, from a top view of the shield portions 142, 143, the shield portions 142, 143 may be in a circular shape or an ellipse shape. Referring to FIG. 2C, in some embodiments, from a top view of the shield portions 142, 143, each of the shield portions 142, 143 may include multiple rectangular-shaped sections to form a polygon shape. In the present embodiment, as the number of the rectangular-shaped sections of each shield portion 142, 143 is increased, an overall shape of the shield portions 142, 143 from the top view thereof may approximately approach to a circular shape and an ellipse shape as shown in FIG. 2A. However, the present disclosure is not limited herein, any pattern shape of the shield portions 142, 143 that is suitable to peripherally and conformally cover the hybrid bonds 141 of the device structure 130 may be applied in the present disclosure.

In some other embodiments, referring again to FIG. 1, the interconnect structure 140 may further include a dielectric layer 148, an encapsulation layer 146, and dummy pads 147. Referring to FIG. 1, the conductive layers 144 and the conductive vias 145 may be embedded in the dielectric layer 148, and a portion of the conductive layer 144 and the bonding via shielding portions 134 may be exposed from the dielectric layer 148. In some embodiments, the encapsulation layer 146 may cover and encapsulate the dielectric layer 148. The dummy pads 147 may be embedded in the encapsulation layer 146 with a surface being exposed therefrom for bonding alignment with the wafer structure 110. As shown in FIG. 1 and FIG. 2A to FIG. 2C, the hybrid bonds 141 and the shielding portions 142, 143 may be embedded in the encapsulation layer 146 with end surfaces being exposed therefrom for connection with the hybrid bonds 121 and the shielding portions 122, 123 located in the wafer structure 110 correspondingly.

In the present embodiment, referring again to FIG. 1 and FIG. 2A to FIG. 2B, the wafer structure 110, bonded to the device structure 130, may include a wafer substrate 111, a redistribution layer 112, and an interconnect structure 120. The interconnect structure 120 may include hybrid bonds 121 and shielding portions 122, 123. The redistribution layer 112 is disposed on the wafer substrate 111 with electrical interconnection therebetween. In some embodiments, the hybrid bonds 121 may be electrically connected to the redistribution layer 112 and the hybrid bonds 121 of the wafer structure 110. In the present embodiment, the shielding portions 122, 123 of the wafer structure 130 and the redistribution layer 112 may be electrically connected to each other through interconnection therebetween. Referring again to FIG. 1 and FIG. 2A to FIG. 2B, the shielding portions 122, 123 may peripherally cover the hybrid bonds 121 for shielding the hybrid bonds from EMI generated from electric potential difference between the adjacent elements located within the package structure 100. In the present embodiment, the shielding portions 122, 123 may be electrically grounded to the wafer substrate 111 through the redistribution layer 112 for EMI shielding of the hybrid bonds 121. In some embodiments, the redistribution layer 112 may include multiple conductive layers 112a embedded in a dielectric layer 112b for electrical connection between the interconnect structure 120 and the wafer substrate 111 of the wafer structure 110.

In the present embodiment, the interconnect structure 120 may further include conductive layers 124 and the conductive vias 125 together electrically connected to the hybrid bonds 121 and the shielding portions 122, 123. In the present embodiment, the shield portions 122, 123 may be electrically connected to the redistribution layer 112 through the conductive layers 124 and the conductive vias 125 of the interconnect structure 120.

Referring again to FIG. 1 and FIG. 2A to FIG. 2C, in some embodiments, each of the hybrid bonds 121 may respectively include a bump pad 121b and a bonding via 121a connected to the bump pad 121b. In some embodiments, each of the shield portions 122, 123 may include a pad shield portion 122 and a via shield portions 123 connected to each other. Referring to FIG. 2A and FIG. 2B, each of the pad shield portions 122 may peripherally surround and cover one of the bump pads 121b, and each of the via shield portions 123 may peripherally surround and cover one of the bonding vias 121a. In the present disclosure, the shield portions 122, 123 may conformally accommodate the bump pads 121b and the bonding vias 121a therewithin for EMI shield of the hybrid bonds 121.

Referring to FIG. 2A, in some embodiments, from a top view of the shield portions 122, 123, the shield portions 122, 123 may be in a circular or an ellipse shape. Referring to FIG. 2C, in some other embodiments, from a top view of the shield portions 122, 123, each of the shield portions 122, 123 may include multiple rectangular-shaped sections. In the present embodiment, as the number of the rectangular-shaped sections of each shield portion 122, 123 is increased, an overall shape of the shield portions 122, 123 from the top view thereof may approximately approach to a circular shape or an ellipse shape as shown in FIG. 2A. However, any pattern shape of the shield portions 122, 123 that is suitable to peripherally and conformally cover the hybrid bonds 121 may be applied in the present disclosure.

In some other embodiments, the interconnect structure 120 may further include a dielectric layer 128, an encapsulation layer 126, and dummy pads 127. Referring again to FIG. 1, the conductive layer 124 and conductive vias 125 of the interconnect structure 120 may be embedded in the dielectric layer 128, and a portion of the conductive layer 124 and the bonding via shield portions 123 may be exposed from the dielectric layer 128. In some embodiments, the encapsulation layer 126 may cover and encapsulate the dielectric layer 128, and the dummy pads 127 may be embedded in the encapsulation layer 126 with a surface being exposed therefrom for bonding alignment with the device structure 130. As shown in FIG. 1 and FIG. 2A to FIG. 2B, the hybrid bonding 121 and the shield portions 122, 123 may be embedded in the encapsulation layer 126 with end surfaces being exposed therefrom for electrical connection with hybrid bonds 141 and the shield portions 142, 143 located in the device structure 130 correspondingly.

Referring again to FIG. 1, the package structure 100 may further include an interconnect structure 150. The interconnect structure 150 may be bonded to a surface of the wafer structure 110 opposing to the surface connected to the device structure 130 through a bonding layer 155. In some embodiments, the interconnect structure 150 may include a dielectric layer 151, conductive layers 152, and conductive vias 153. The conductive layers 152 and the conductive vias 153 are embedded in the dielectric layer 151 and connected with each other. In some embodiments, the wafer structure 110 may further include through-vias 115 penetrated through the redistribution layer 112 and the wafer substrate 111. In the present embodiment, the conductive layers 152 of the interconnect structure 150 may be electrically connected to the conductive layers 112a of the redistribution layer 112 of the wafer structure 110 via the through-vias 115. In the present embodiment, a pitch between each two closest adjacent through-vias 115 may be about 6 microns (μm). In some embodiments, the interconnect structure 150 may further include a dielectric layer 157 and a conductive feature 158 embedded therein. In some embodiments, the conductive feature 158 may be referred to as, for example, an Under-Bump-Metallurgy (UBM) pattern. The conductive feature 158 may be electrically connected to the conductive layers 152 through the conductive vias 156. In some embodiments, external connection elements 190, such as solder balls, may be further configured as connected to the conductive feature 158 for external electrical connection to, for example, another device chips or a plastic circuit board (PCB) substrate.

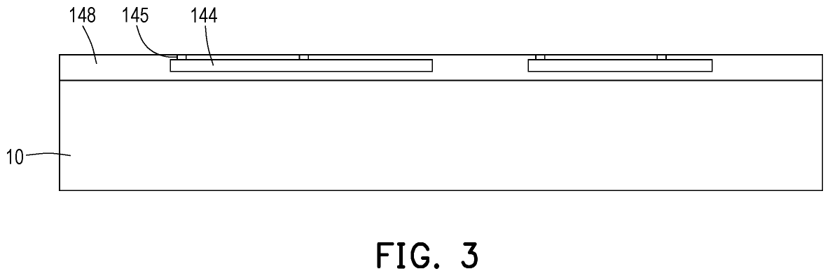

FIG. 3 to FIG. 11 are schematic cross-sectional views of various stages in a manufacturing method of a package structure 100 according to some exemplary embodiments of the disclosure. In exemplary embodiments, the manufacturing method is part of a wafer level packaging process. It is to be noted that the process steps described herein cover a portion of the manufacturing processes used to fabricate a package structure. The embodiments are intended to provide further explanations but are not used to limit the scope of the present disclosure. In FIG. 3 to FIG. 11, one (semiconductor) chip or die is shown to represent plural (semiconductor) chips or dies of the wafer, and a package structure 100 is shown to represent a package structure obtained following the manufacturing method, for example. In other embodiments, two (semiconductor) chips or dies are shown to represent plural (semiconductor) chips or dies of the wafer, and one or more package structures are shown to represent plural (semiconductor) package structures obtained following the (semiconductor) manufacturing method, the disclosure is not limited thereto.

Referring to FIG. 3, in the present embodiment, an interposer is formed, and the interposer includes a semiconductor carrier 10, and the interconnect structure 140 includes the conductive layers 144, the connective vias 145, and the dielectric layer 148. In the present embodiment, the semiconductor carrier 10 may be formed of crystalline silicon, crystalline germanium, crystalline silicon germanium, and/or a III-V compound semiconductor such as GsAsP, AlInAs, AlGaAs, GalnAs, GalnP, GalnAsP, and the like. In some embodiments, semiconductor carrier 10 may also be formed of other rigid materials such as glass, silicon oxide, silicon carbide, or the like. In some embodiments, the semiconductor carrier 10 may also be a bulk silicon substrate.

The conductive layers 144, the conductive vias 145, and the dielectric layer 148 of the interconnect structure 140 are formed over the semiconductor carrier 10 sequentially after the formation of the semiconductor carrier 10. In some embodiments, the dielectric layer 148 may be made of or include silicon oxide, silicon oxynitride, borosilicate glass (BSG), phosphoric silicate glass (PSG), borophosphosilicate glass (BPSG), fluorinated silicate glass (FSG), low-k material, porous dielectric material, one or more other suitable materials, or a combination thereof. In some embodiments, the dielectric layer 148 is deposited over the semiconductor carrier 10 using a CVD process, an ALD process, a FCVD process, a PVD process, one or more other applicable processes, or a combination thereof. In some embodiments, etch stop layers (not shown) may formed on the semiconductor carrier 10 during the above formation process.

In some embodiments, the conductive layers 144 and the conductive vias 145 may be formed of copper or copper alloys, or other suitable metals. The formation process of the conductive layers 144 and the conductive vias 145 may include a single damascene process and dual damascene process. In the embodiment of the single damascene process, a trench is firstly formed in the dielectric layer 148, followed by filling the trench with a conductive material. Moreover, a planarization process such as a Chemical Mechanical Polish (CMP) process is then performed to remove the excess position of the conductive material. In the embodiment of the dual damascene process, both a trench and a via opening are formed with the vias opening underlaying and connected to the trench. The conductive material is then filled into the trench and the via opening to form the conductive layers 144 and the conductive vias 145 respectively.

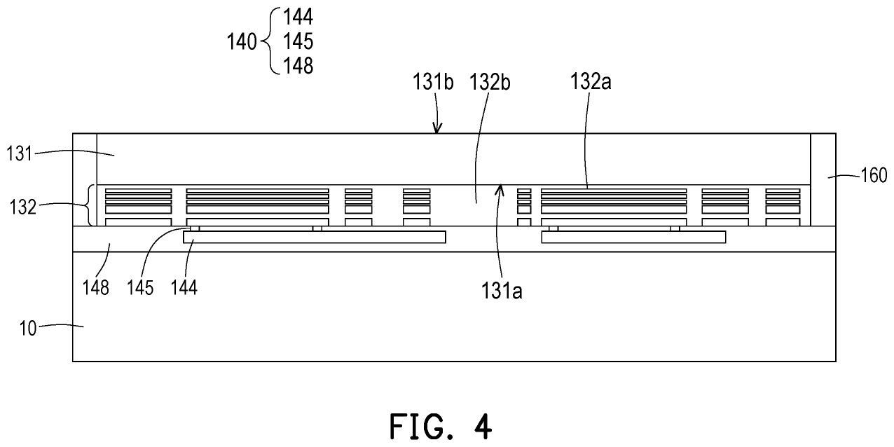

Referring to FIG. 4, the device die 131 of the device structure 130 is bonded to the interconnect structure 140 of the interposer through the redistribution layer 132 and a first surface 131a thereof. In some embodiments, the redistribution layer 132 may be formed with the dielectric layer 132b and the conductive layers 132a embedded therein. The redistribution layer 132 may be formed between a first surface 131a of the device die 131 and the interconnect structure 140. In the present embodiment, the conductive vias 143 of the interconnect structure 140 is electrically connected to the conductive layers 132a of the redistribution layer 132.

In certain embodiments, the material of the dielectric layers 132b of the redistribution layer 132 may be polyimide, PBO, BCB, a nitride such as silicon nitride, an oxide such as silicon oxide, PSG, BSG, BPSG, a combination thereof or the like, which may be patterned using a photolithography and/or etching process. In some embodiments, the material of the dielectric layers 132b are formed by suitable fabrication techniques such as spin-on coating process, chemical vapor deposition CVD process, plasma-enhanced chemical vapor deposition PECVD process or the like. The disclosure is not limited thereto.

In some embodiments, the material of the conductive layer 132a of the redistribution layer 132 may be made of conductive materials formed by electroplating or deposition, such as aluminum, titanium, copper, nickel, tungsten, and/or alloys thereof, which may be patterned using a photolithography and etching process. In some other embodiments, the conductive layer 132a may be patterned copper layers or other suitable patterned metal layers. Throughout the description, the term “copper” is intended to include substantially pure elemental copper, copper containing unavoidable impurities, and copper alloys containing minor amounts of elements such as tantalum, indium, tin, zinc, manganese, chromium, titanium, germanium, strontium, platinum, magnesium, aluminum or zirconium, etc.

Referring again to FIG. 4, the encapsulation layer 160 may be subsequentially formed to peripherally surround and encapsulate the device die 131 after the device die 131 of the device structure 130 being bonded to the interconnect structure 140. In some embodiments, the encapsulation layer 160 may include a polymer material such as polybenzoxazole (PBO), polyimide, benzocyclobutene (BCB), a combination thereof, or the like, and is formed by a molding process followed by a grinding process until a second surface 131b of the device die 131 is exposed from the encapsulation layer 160.

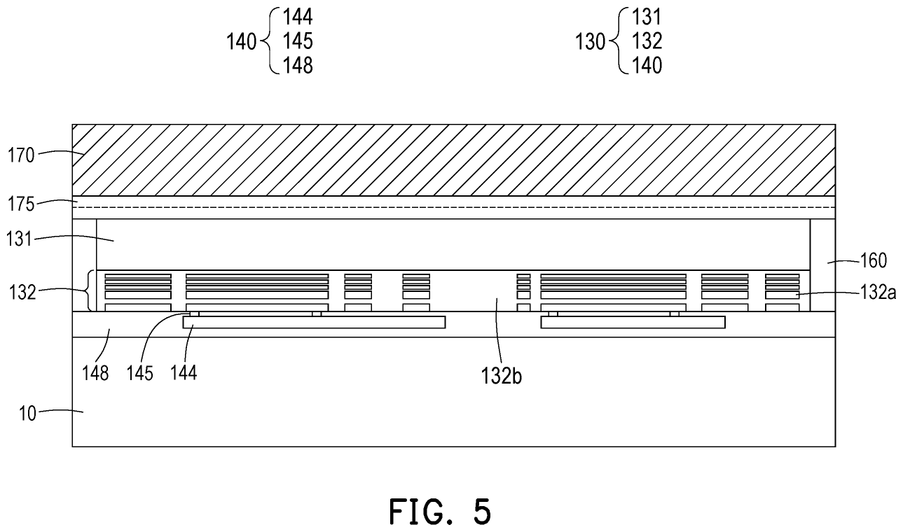

Referring to FIG. 5, a surface of the encapsulation layer 160 and the second surface 131b of the device die 131 exposed from the encapsulation layer 160 may be attached to the support silicon substrate 170 through an adhesive layer 175. In some embodiments, the adhesive layer 175 may be referred to as an adhesive film or other suitable dielectric bonding films.

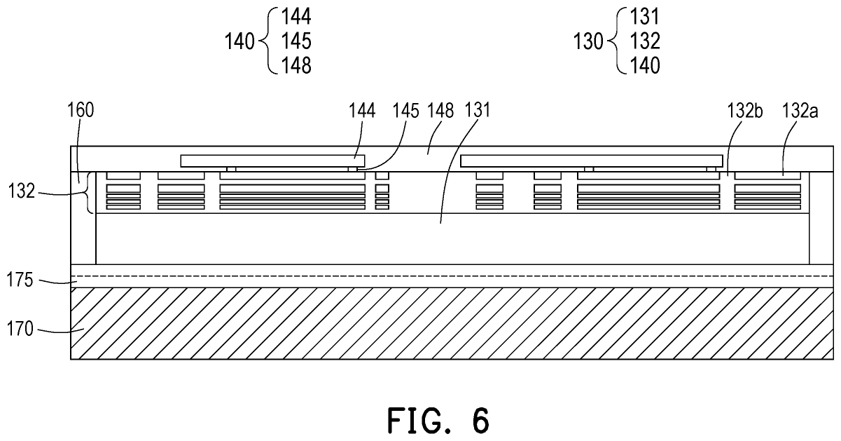

Referring to FIG. 6, after bonding the device die 131, the redistribution layer 132 of the device structure 130, the interconnect structure 140, and the semiconductor carrier 10 of the interposer being bonded to the support silicon substrate 170, the entire structure shown in FIG. 5 may be flipped upside-down. As shown in FIG. 6, the semiconductor carrier 10 may be deboned from the interconnect structure 140. In an alternative embodiment not illustrated, the semiconductor carrier 10 may be coated with a debond layer for debonding the semiconductor carrier 10 from the interconnect structure 140. The material of the debond layer may be any material suitable for bonding and debonding the semiconductor carrier 10 from the interconnect structure 140 and the device structure 130.

In some embodiments, the above-mentioned debond layer may include a dielectric material layer made of a dielectric material including any suitable polymer-based dielectric material (such as benzocyclobutene (“BCB”), polybenzoxazole (“PBO”)). In an alternative embodiment, the debond layer may include a dielectric material layer made of an epoxy-based thermal-release material, which loses its adhesive property when heated, such as a light-to-heat-conversion (LTHC) release coating film. In a further alternative embodiment, the debond layer may include a dielectric material layer made of an ultra-violet (UV) glue, which loses its adhesive property when exposed to UV lights. In certain embodiments, the debond layer may be dispensed as a liquid and cured, or may be a laminate film laminated onto the semiconductor carrier 10, or may be the like. In certain embodiments, the debond layer is, for example, a LTHC layer with good chemical resistance, and such layer enables room temperature debonding the semiconductor carrier 10 from the interconnect structure 140 by applying laser irradiation, however the disclosure is not limited thereto.

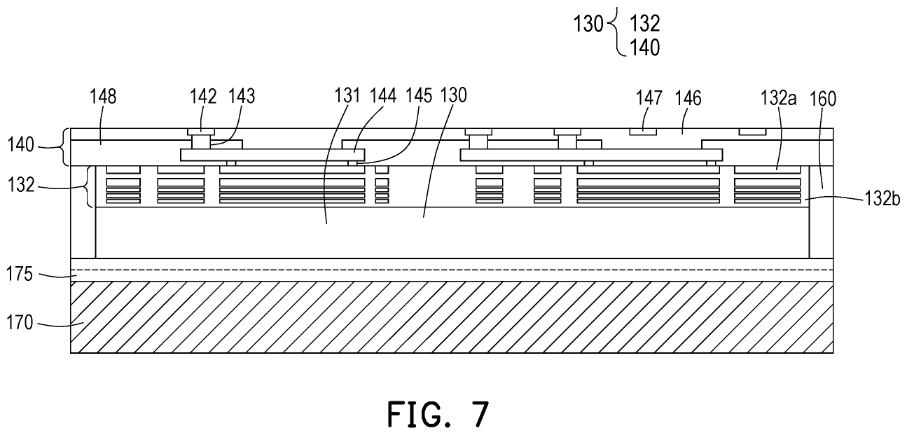

Referring to FIG. 2 and FIG. 7, in some embodiments, the hybrid bonds 141 and the shield portions 142, 143 peripherally surrounding and covering the hybrid bonds 141 are formed to be electrically connected with the conductive layers 144 and the conductive vias 145. Moreover, the hybrid bonds 141 and the shield portions 142, 143 are encapsulated by encapsulation layer 146. In the present embodiment, the hybrid bonds 141 and the shield portions 142, 143 may be formed by simultaneously patterned using a photolithography and etching process in the dielectric layer 148 and the encapsulation layer 146. In some embodiments, the hybrid bonds 141 and the shield portions 142, 143 may be patterned copper layers or other suitable patterned metal layers. Throughout the process, the hybrid bonds 141 and the shield portions 142, 143 are deposited and formed to be exposed and protruded from the dielectric layer 148. In the present embodiment, an encapsulation material might be further deposited to form the encapsulation layer 146 that covers the hybrid bonds 141 and the shield portions 142, 143. The encapsulation material, for example, may include polymers (such as epoxy resin, phenolic resins, silicon-containing resins, or other suitable resins), and dielectric materials having low permittivity (Dk) and low loss tangent (Df) properties, or other suitable materials. In some alternative embodiments, the encapsulation material may further include inorganic filler or inorganic compound (e.g. silica, clay, and so on) which can be added therein to optimize coefficient of thermal expansion (CTE) of the encapsulation material. The disclosure is not limited thereto.

In some embodiments, the encapsulation material may be planarized by mechanical grinding or chemical mechanical polishing (CMP), for example, to form the encapsulation layer 146 that exposes top surfaces of the hybrid bonds 141 and shield portions 142, 143 as shown in FIG. 2A and FIG. 2C. After the planarization step, a cleaning step may be optionally performed, for example to clean and remove the residue generated from the planarization step. However, the disclosure is not limited thereto, and the planarization step may be performed through any other suitable method. In certain embodiments, referring to FIG. 2C, from a top view of the hybrid bonds 141 and the shield portions 142, 143, the forming patterns of the shield portions 142, 143 may include multiple rectangular-shaped sections. With increasing the number of the rectangular-shaped sections of the shield portions 142, 143, the overall patterns of the shield portions 142, 143 may approximately approach to a circular shape or an eclipse shape as shown in FIG. 2A of the present disclosure. However, from a top view, any pattern shape of the shield portions 142, 143 that is suitable to peripherally surround and cover the hybrid bonds 141 may be also applied in the present disclosure.

In the present embodiment, referring again to FIG. 2 and FIG. 7, the above stage of forming the hybrid bonds 141 may include forming the bonding vias 141a and the bump pads 141b sequentially. In some other embodiments, the above stage of forming the shield portions 142, 134 may include forming the pad shield portions 142 and the via shield portions 143 sequentially. In the present embodiment, the bonding vias 141a may be formed simultaneously with the via shield portions 143, and the bump pads 141b may be formed simultaneously with the pad shield portions 142 for EMI shielding.

In some embodiments, during the stage of forming the bump pads 141b and the pad shield portions 142, the dummy pads 147 may be formed in the encapsulation layer 146 at the same level as the bump pads 141b and the pad shield portions 143 for bonding alignment between the device structure 130 and the wafer structure 110. In the present embodiments, the dummy pads 147 may be isolated and inactive pads, which are not electrically connected to other elements. Namely, in the present embodiment, no electrical signal passes through these dummy pads 147 during operation of the package structure 100.

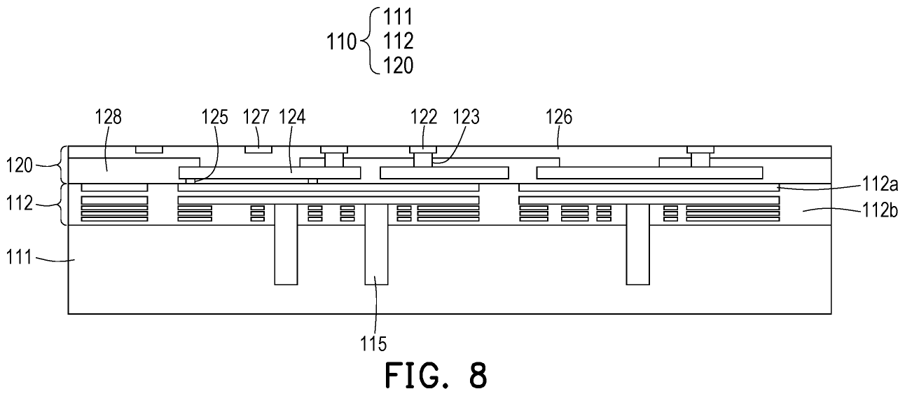

Referring to FIG. 8, after forming the device structure 130 through the above steps of the manufacturing process, a wafer structure 110 may be further provided as shown in FIG. 8. In some embodiments, the forming process and forming materials of the redistribution layer 112 disposed on the wafer substrate 111 may be similar or the same with the forming process and forming materials of the redistribution layer 132 of the device structure 130. In some other embodiments, the forming process and forming materials of the interconnect structure 120 disposed on a surface of the redistribution layer 112, opposing to a surface of the redistribution layer 112 attached with the wafer substrate 111, may be similar or the same with the forming process and forming materials of the interconnect structure 140 of the device structure 130.

It should be further noted that, in the present embodiment, the step of forming the interconnect structure 120 may also further including forming the dummy pads 127 in the encapsulation layer 126 at the same level as the bump pads 121b and the pad shield portions 123 for bonding alignment between the device structure 130 and the wafer structure 110. In the present embodiments, the dummy pads 127 may be isolated and inactive pads, which are not electrically connected to any element. Namely, in the present embodiment, no electrical signal passes through these dummy pads 127 during operation of the package structure 100.

In the present embodiment, referring to FIG. 8, the step of forming the wafer structure 110 may further includes forming the plural through-vias 115. Each of the through-vias 115 may be formed as being extended through an interface between the redistribution layer 112 and the wafer substrate 111 to electrically connect the conductive vias 112a of the redistribution layer 112.

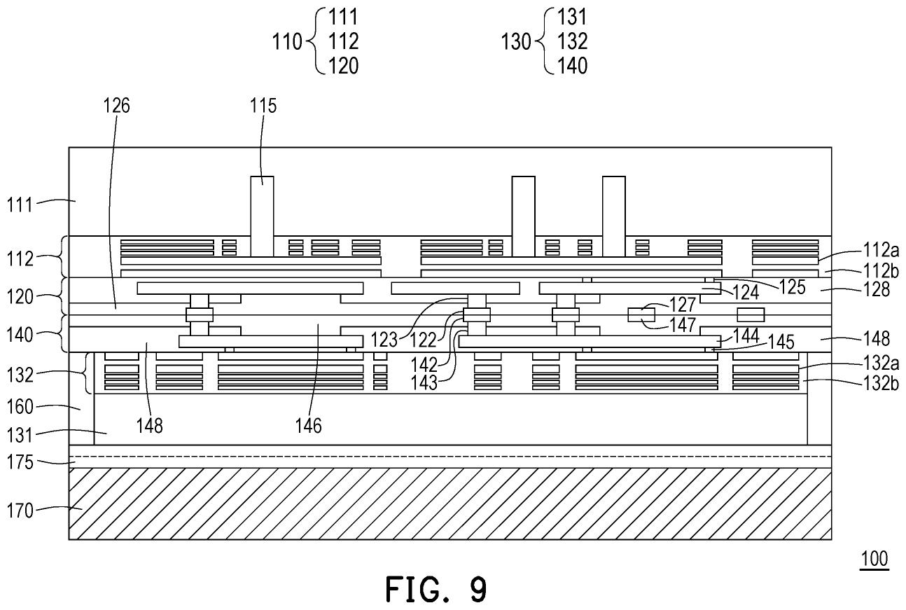

Referring to FIG. 9, in the present embodiment, after forming the wafer structure 110 as shown in FIG. 8, the entire structure is flipped upside-down for being bonded to the device structure 130 shown in FIG. 7. Referring to FIG. 9, in the present embodiment, the bonding between the bump pads 141b, 121b, the pad shield portions 122, 142, and the dummy pads 127, 147 of the device structure 130 and the wafer structure 110 may be achieved through hybrid bonding. For example, the bump pads 141b and the pad shield portions 142 are bonded to the bump pads 121b and the pad shield portions 122 through metal-to-metal direct bonding. In accordance with some embodiments of the present disclosure, the metal-to-metal direct bonding includes a copper-to-copper direct bonding. In some embodiments, the bump pads 141b, 121b, the pad shield portions 122, 142, and the dummy pads 127, 147 may be bonded correspondingly through direct metal bonding caused by, for example, metal inter-diffusion.

In the present embodiment, the encapsulation layer 126 of the interconnect structure 120 and the encapsulation layer 146 of the interconnect structure 140 may be bonded through fusion bonding. In some embodiments, the encapsulation layer 126 and the encapsulation layer 146 may be formed of a dielectric material that is suitable for fusion-bonding, which may be formed of or comprise silicon oxide, silicon nitride, silicon oxynitride or the like.

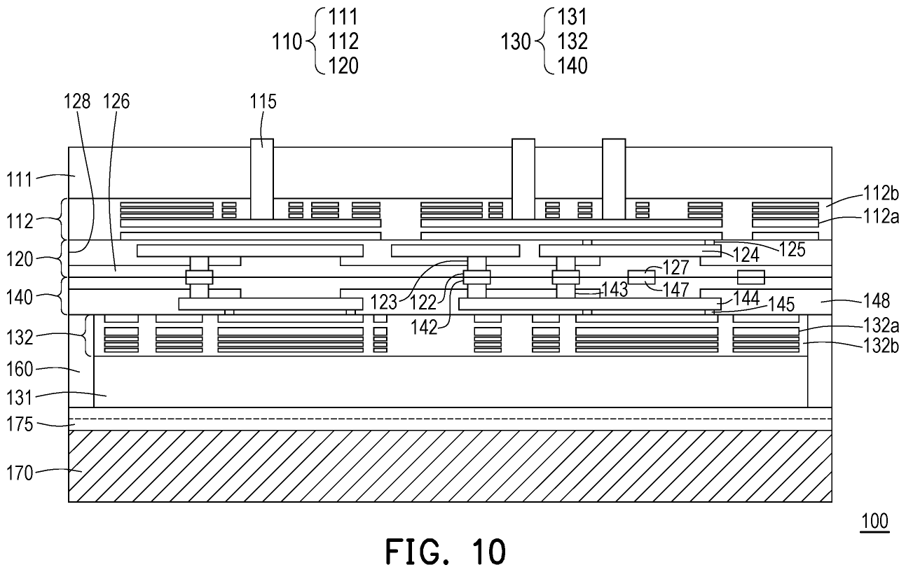

Referring to FIG. 10, in the present embodiment, the surface of the wafer substrate 111 is etched to expose the through-vias 115 for external electrical connections. In some embodiments, the surface of the wafer substrate 111 may be partially removed using an etching process, such as an anisotropic etching process.

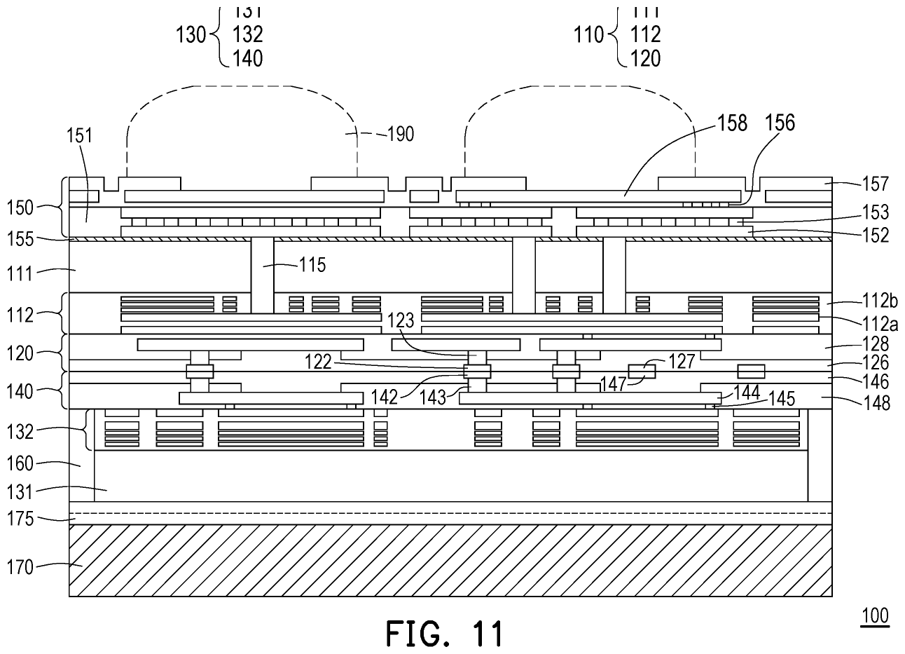

Referring to FIG. 11, the interconnect structure 150 may be further bonded to the surface of the wafer structure 110, opposing to the surface of the wafer structure 110 connected to the device structure 130, through the bonding layer 155. In the present embodiment, a bonding material may be deposited on the wafer substrate 111 and the through-vias 115, and a planarization process, such as mechanical grinding or CMP may be applied to the bonding material for exposing the top surfaces of the through-vias 115 and for forming the bonding layer 155. In the present embodiment, the bonding material may be any solid phase material or mixed material that can be deposited or formed at low temperatures and is polished to a sufficiently smooth surface. As shown in FIG. 11, the top surfaces of the through-vias 115 are flush with the surface of the bonding layer 155.

In the present embodiment, the step of forming the interconnect structure 150 may include forming the dielectric layer 151, the conductive layer 152, and the conductive vias 153. In the present embodiment, the forming process of the dielectric layer 151, the conductive layers 152, and the conductive vias 153 may be the same or similar with the dielectric layer 148, the conductive layers 144, and the conductive vias 145 of the interconnect structure 140, and thus the same or similar descriptions would not be repeated herein. Referring again to FIG. 11, in the present embodiments, the through-vias 115 protruded from the wafer substrate 111 may be electrically connected with the conductive vias 152.

In the present embodiment, the forming process of the interconnect structure 150 may further include forming the dielectric layer 157 on the dielectric layer 151, and the conductive feature 158 may be formed as being embedded in the dielectric layer 157. In some embodiments, the conductive feature 158 may be formed as a UBM pattern. In the present embodiment, the materials of the UBM patterns 158 may include copper, nickel, titanium, tungsten, or alloys thereof or the like, and may be formed by an electroplating process, for example.

Referring to FIG. 11, in some embodiments, the external connection elements 190 may be disposed on the UBM patterns 158 by ball placement process or reflow process. In some embodiments, the conduction elements 190 are, for example, solder balls or ball grid array (BGA) balls. In some embodiments, the connection elements 190 are connected to the redistribution layer 112 through the UBM patterns 158 and through-vias 115. The number of the connection elements 190 is not limited to the disclosure and may be designated and selected based on the number of the UBM patterns 158 disposed in the interconnect structure 150. To the stage of the process shown in FIG. 11, the entire package structure 100 is completed.

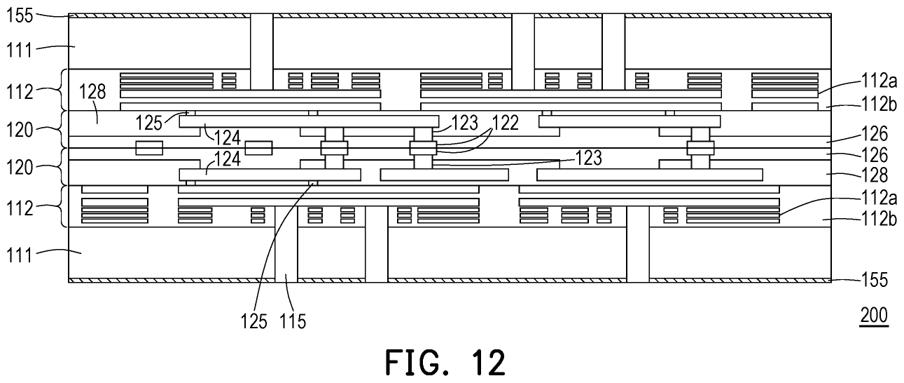

FIG. 12 is a schematic cross-sectional view of a package structure 200 according to some exemplary embodiments of the disclosure. In the current embodiment, the package structure 200 is distinct from the package structure 100 of the previous embodiment in that the package structure 200 may include two wafer structures 110 that are hybrid bonded to each other in a wafer-to-wafer bonding manner. Referring to FIG. 2 and FIG. 12, in the present embodiments, the upper and lower wafer structures 110 may be bonded together through the respective hybrid bonds 121 of the interconnect structure 120. The shield portions 122, 123 peripherally surround and cover the hybrid bonds 121 that are configured for wafer-to-wafer bonding between the upper and lower wafer structures 110. In the present embodiment, the hybrid bonds 121 of the respective upper and lower wafer structures 110 may be electrically grounded to the upper and lower wafer substrates 111 through the electrical connections of the hybrid bonds 121 with the redistribution layers 112 for EMI shielding of the hybrid bonds 121. In some other embodiments not illustrated, the hybrid bonds and the shield portions peripherally surrounding and covering the hybrid bonds may be also applied to a die-to-die bonding between, for example, two device structures 130 shown in FIG. 1 and FIG. 11.

In some embodiments, referring to FIG. 1, FIG. 11, and FIG. 12, in some other embodiments, the wafer structure 110 shown in FIG. 12 may also include through-vias 115, as shown in FIG. 1 and FIG. 11, penetrating through the wafer substrate 111 to electrically connect with the external connection elements 190, such as the solder balls, for external electrical connection with additional devices, such as other IC chips, or additional substrates, such as a PCB substrate.

In accordance with some embodiments, a package structure includes a package structure includes a device structure and a wafer structure. The wafer structure is bonded to the device structure. The device structure includes a device die, a first redistribution layer, first hybrid bonds, and first shield portions. The first redistribution layer is disposed on the device die. The first hybrid bonds are electrically connected to the first redistribution layer. The first shield portions peripherally cover the first hybrid bonds for shielding the first hybrid bonds from electromagnetic interference (EMI). The first shield portions are electrically grounded to the device die through the first redistribution layer. The wafer structure includes a wafer substrate, a second redistribution layer, second hybrid bonds, and second shield portions. The second redistribution is disposed on the wafer substrate. The second hybrid bonds are respectively connected to the first hybrid bonds and the second redistribution layer. The second shield portions are respectively connected to the first shield portions and the second redistribution layer. The second shield portions peripherally cover the second hybrid bonds for shielding the second hybrid bonds from EMI. The second shield portions are electrically grounded to the wafer substrate through the second redistribution layer.

In accordance with some embodiments, a package structure includes a first wafer structure and a second wafer structure. The second wafer structure is bonded to the first wafer structure. The first wafer structure includes a first semiconductor substrate, a first redistribution layer, first hybrid bonds, and first shield portions. The first redistribution layer is disposed on the semiconductor substrate. The first hybrid bonds are electrically connected to the first redistribution layer. The first shield portions peripherally cover the first hybrid bonds. The first shield portions are electrically grounded to the first semiconductor substrate through the first redistribution layer for shielding the first hybrid bonds from EMI. The second semiconductor substrate includes a second semiconductor substrate, a second redistribution layer, second hybrid bonds, and second shield portions. The second redistribution layer is disposed on the second semiconductor substrate. The second hybrid portions are electrically connected to the second redistribution layer and the first hybrid bonds. The second shield portions are connected to the first shield portions and grounded to the second semiconductor substrate for shielding the second hybrid bonds from EMI.

In accordance with some embodiments, a method of manufacturing a package structure is provided with the following steps, forming an interposer; bonding a device die to the interposer through a first redistribution layer including first conductive layers; encapsulating the device die through an encapsulation material; bonding a supporting substrate to the device die through an adhesive layer; removing the semiconductor to expose the first interconnect structure; forming first hybrid bonds and first shield portions peripherally cover the first hybrid bonds; forming a wafer structure; forming a second interconnect structure; forming a second redistribution layer; and bonding the wafer structure to the device die through the first hybrid bonds and the second hybrid bonds. The step of forming the interposer includes providing a semiconductor carrier and forming the first interconnect structure over the semiconductor carrier. The first redistribution layer is formed between the surface of the device die and the interposer. The first conductive vias of the first interconnect structure is electrically connected to the first conductive layers of the first redistribution layer. The step of forming the wafer layer includes forming a wafer substrate; forming a second interconnect structure; and forming a second redistribution layer. The second interconnect structure includes the second hybrid bonds and the second shield portions peripherally covering the second hybrid bonds. The second redistribution layer, including the second conductive layers, is disposed between the wafer substrate and the second interconnect structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a device structure, comprising;
a device die;
a first redistribution layer, disposed on the device die;
a plurality of first hybrid bonds, electrically connected to the first redistribution layer; and
a plurality of first shield portions, peripherally covering the plurality of first hybrid bonds for shielding the plurality of first hybrid bonds from electromagnetic interference (EMI),
wherein the plurality of the first shield portions is electrically grounded to the device die through the first redistribution layer; and
a wafer structure, bonded to the device structure, comprising;
a wafer substrate;
a second redistribution layer, disposed on the wafer substrate;
a plurality of second hybrid bonds, respectively connected to the second redistribution layer and the plurality of first hybrid bonds; and
a plurality of second shield portions, respectively connected to the plurality of first shield portions and the second redistribution layer, peripherally covering the plurality of second hybrid bonds for shielding the plurality of second hybrid bonds from EMI,
wherein the plurality of second shield portions is electrically grounded to the wafer substrate through the second redistribution layer.

2. The package structure of claim 1, wherein the plurality of first hybrid bonds respectively comprises first bump pads and first bonding vias connected to each other.

3. The package structure of claim 2, wherein the plurality of first shield portions respectively comprises first pad shield portions and first via shield portions connected to each other,
wherein the first pad shield portions peripherally cover the first bump pads, and the first via shield portions peripherally cover the first bonding vias.

4. The package structure of claim 2, further comprising a plurality of first dummy pads respectively aligned with the first bump pads at the same vertical level in the device structure.

5. The package structure of claim 1, wherein the plurality of second hybrid bonds respectively comprises second bump pads and second bonding vias connected to each other.

6. The package structure of claim 5, wherein the plurality of second shield portions respectively comprises second pad shield portions and second via shield portions connected to each other,
wherein the second pad shield portions peripherally cover the second bump pads, and the second via shield portions peripherally cover the second bonding vias.

7. The package structure of claim 5, further comprising a plurality of second dummy pads respectively aligned with the second bump pads at the same vertical level in the wafer structure.

8. The package structure of claim 1, wherein the plurality of first shield portions and the second shield portions are respectively in a circular shape or an eclipse shape from a top view of the package structure.

9. The package structure of claim 1, wherein the plurality of first shield portions and the second shield portions are respectively in a polygonal shape from a top view of the package structure.

10. A package structure, comprising:
a first wafer structure, comprising;
a first semiconductor substrate;
a first redistribution layer, disposed on the semiconductor substrate;
a plurality of first hybrid bonds, electrically connected to the first redistribution layer; and
a plurality of first shield portions, peripherally covering the plurality of first hybrid bonds, wherein the plurality of first shield portions is electrically grounded to the first semiconductor substrate through the first redistribution layer for shielding the plurality of first hybrid bonds from EMI; and
a second wafer structure, bonded to the first wafer structure, comprising:
a second semiconductor substrate;
a second redistribution layer, disposed on the second semiconductor substrate;
a plurality of second hybrid bonds, electrically connected to the second redistribution layer and the plurality of first hybrid bonds; and
a plurality of second shield portions, peripherally covering the plurality of second hybrid bonds, wherein the plurality of second shield portions is connected to the plurality of first shield portions and grounded to the second semiconductor substrate for shielding the plurality of second hybrid bonds from EMI.

11. The package structure of claim 10, wherein the plurality of the first hybrid bonds comprises first bump pads and the first bonding vias connected to each other, and the plurality of the second hybrid bonds respectively comprise second bump pads and the second bonding vias connected to each other,
wherein the first bump pads are respectively connected to the second bump pads.

12. The package structure of claim 10, wherein the first wafer structure comprises a plurality of first dummy pads, and the second wafer structure comprises a plurality of second dummy pads, wherein the plurality of first dummy pads is aligned with the second dummy pads along a thickness direction of the package structure for bonding alignment between the first wafer structure and the second wafer structure.

13. The package structure of claim 10, further comprising external connection elements, wherein the first wafer structure further comprises through-vias electrically connected to the external connection elements for external electrical connection.

14. A method of manufacturing a package structure, comprising:
forming an interposer comprising;
providing a semiconductor carrier; and
forming a first interconnect structure over the semiconductor carrier, wherein the first interconnect structure comprises a plurality of conductive layers and a plurality of conductive vias connected to each other;
bonding a device die to the interposer through a first redistribution layer comprising a plurality of first conductive layers, wherein the first redistribution layer is formed between a first surface of the device die and the interposer, and the plurality of first conductive vias of the first interconnect structure is electrically connected to the plurality of first conductive layers of the first redistribution layer;
encapsulating the device die through an encapsulation material;
bonding a supporting substrate to the device die through an adhesive layer;
removing the semiconductor carrier to expose the first interconnect structure;
forming a plurality of first hybrid bonds and a plurality of first shield portions peripherally covering the plurality of first hybrid bonds;
forming a wafer structure, comprising:
forming a wafer substrate;
forming a second interconnect structure, wherein the second interconnect structure comprises a plurality of second hybrid bonds and a plurality of second shield portions peripherally covering the plurality of the second hybrid bonds; and
forming a second redistribution layer, wherein the second redistribution layer, comprising a plurality of second conductive layers, is disposed between the wafer substrate and the second interconnect structure; and
bonding the wafer structure to the device die through the plurality of first hybrid bonds and the plurality of second hybrid bonds.

15. The method of claim 14, wherein the step of forming the plurality of first hybrid bonds comprises:
forming a plurality of first bump pads and a plurality of first bonding vias connected each other.

16. The method of claim 15, wherein the step of forming the plurality of first shield portions comprises:
forming a plurality of first pad shield portions, peripherally covering the plurality of first bump pads; and
forming a plurality of first via shield portions, connected to the plurality of first pad shield portions, peripherally covering the plurality of first bonding vias.

17. The method of claim 14, wherein the step of forming the plurality of second hybrid bonds comprises:
forming a plurality of second bump pads and a plurality of second bonding vias connected to each other.

18. The method of claim 17, wherein the step of forming the plurality of second shield portions comprises:
forming a plurality of second pad shield portions, peripherally covering the plurality of second bump pads; and
forming a plurality of second via shield portions, connected to the plurality of second pad shield portions, peripherally covering the plurality of second bonding vias.

19. The method of claim 14, further comprising forming dummy pads respectively in the first interconnect structure and the second interconnect structure for bonding alignment between the device die and the wafer structure.

20. The method of claim 14, wherein the plurality of first shield portions and the plurality of second shield portions are formed of a copper metal.
